(19) United States
(12) Patent Application Publication
(10) Pub. No.: US 2022/0344905 A1
(43) Pub. Date: Oct. 27, 2022

(54) SEMICONDUCTOR LASER DEVICE AND PROJECTION DEVICE

(71) Applicant: OSRAM Opto Semiconductors GmbH, Regensburg (DE)

(72) Inventors: Hubert HALBRITTER, Dietfurt (DE); Ann RUSSELL, San Jose, CA (US)

(21) Appl. No.: 17/235,996

(22) Filed: Apr. 21, 2021

(51) Int. Cl. H01S 5/34; H01S 5/11; H01S 5/40; G03B 21/20

(52) U.S. Cl. CPC H01S 5/34; H01S 5/11; H01S 5/4012; G03B 21/2033

(57) ABSTRACT

A semiconductor laser device comprises an active layer having a main extension plane, a first cladding layer and a second cladding layer where the active layer is arranged between the first and second cladding layer in a direction perpendicular to the main extension plane, at least one first emission region and at least one second emission region arranged next to each other in a direction parallel to the main extension plane, a light-outcoupling surface parallel to the main extension direction and arranged on a side of the second cladding layer opposite to the active layer, and a photonic crystal layer arranged in the first cladding layer or in second cladding layer. The photonic crystal layer may include a first photonic crystal structure in the first emission region and a second photonic crystal structure in the second emission region where the first and the second photonic crystal structures are different.

### TECHNICAL FIELD

A semiconductor laser device and a projection device are specified.

### BACKGROUND

Compared to bulb-based projection devices, the use of lasers as light sources in projection applications offers numerous advantages. Since laser projectors, for example, offer near instant on/off functionality, no heating and cooling down times are required as is the case with light bulbs.

Furthermore, light bulbs are limited in regard to their light intensity, which may even drop during the lifetime of the light bulbs. Lasers create only the color needed to produce the image. In contrast, laser light sources may offer a high intensity output, which may lead to a high optical efficiency in the projector. Furthermore, the lifetime of a laser is typically much larger than that of light bulbs, while the output power does not degrade strongly during the lifetime of the laser.

However, the coherent light produced by lasers may lead to interferences, for instance so-called speckles, in the observed image. A speckle pattern is a granular pattern of spots which is overlaid on the projected image. A speckle pattern arises due to the quasi-random interference that is generated because the coherent laser beam is scattered from a projection screen that is rough on the scale of the optical wavelength. Moreover, typically edge-emitting laser diodes are used as laser light sources. This type of laser diode emits a light beam with different divergences along the slow axis and the fast axis. Thus, complex optics including cut-off apertures and various lenses have to be used to provide a light beam with a small and symmetrical divergence. As a consequence, usually a large percentage, which may amount up to 60%, of the originally produced light is lost due to the beam shaping optics.

At least one object of particular embodiments is to provide a semiconductor laser device. At least one further object of particular embodiments is to provide a projection device.

### SUMMARY

According to at least one embodiment, a semiconductor laser device may include at least one active layer configured to generate light in at least one active region during operation of the semiconductor laser device. Here and in the following, “light” refers to electromagnetic radiation in an infrared to ultraviolet wavelength range. In particular, the active layer may be part of a semiconductor layer sequence having a plurality of semiconductor layers and may have a main extension plane perpendicular to an arrangement direction of the layers of the semiconductor layer sequence. The light generated in the active layer, and especially in the active region during operation of the semiconductor laser diode, may be emitted via a light-outcoupling surface.

For example, the active layer may have exactly one active region. The active region may at least partially be defined by a contact surface of one or more electrical contact layers with the semiconductor layer sequence, i.e., at least partially by a surface through which current is injected into the semiconductor layer sequence and thus into the active layer. Furthermore, the active region may at least partially also be defined by structured semiconductor layers like, for instance current-spreading and current-delimiting layers in the semiconductor layer sequence. Furthermore, the photonic crystal semiconductor laser device may have one or more reflective layers that may contribute to the definition of an active region.

According to a further embodiment, the semiconductor laser device is embodied as a semiconductor laser diode that has, in addition to the light-outcoupling surface, a rear surface opposite the light-outcoupling surface. The light-outcoupling surface and the rear surface may be main surfaces that are parallel to the main extension direction of the active layer, respectively. Suitable optical coatings or layers, such as reflective or partially reflective layers or layer sequences, which may form an optical resonator for the light generated in the active layer, may be applied to or in the vicinity of the light-outcoupling surface and to or in the vicinity of the rear surface. Directions parallel to the main extension plane of the active region may, here and in the following, be referred to as the lateral directions. The arrangement direction of the layers of the semiconductor layer sequence on top of each other, i.e., a direction perpendicular to the main extension plane of the active layer, may, here and in the following, be referred to as vertical direction. Consequently, the semiconductor laser device may emit light during operation with a main emission direction along the vertical direction.

The semiconductor layer sequence may be embodied as an epitaxial layer sequence in a non-limiting embodiment, i.e., as an epitaxially grown semiconductor layer sequence. In this case, a plurality of semiconductor layers including the active layer may be grown on top of each other. The semiconductor layers may be based on a compound semiconductor material system, respectively.

The semiconductor layer sequence may be based on InAlGaN, for example. InAlGaN-based semiconductor layer sequences may include those in which the epitaxially produced semiconductor layer sequence generally has a layer sequence of different individual layers that contains at least one individual layer having a material from the III-V compound semiconductor material system

InₓAl_{y}Ga_{1-x-y}N-with 0≤x≤1, 0≤y≤1 and x+y≤1. In a non-limiting embodiment, the active layer may be based on such a material. Semiconductor layer sequences that have at least one active layer based on InAlGaN may, for example, emit electromagnetic radiation in an ultraviolet to green or even yellow wavelength range.

Alternatively or additionally, the semiconductor layer sequence may also be based on InAlGaP, i.e., the semiconductor layer sequence may have different individual layers, of which at least one individual layer, for instance the active layer, includes a material made of the III-V compound semiconductor material system InₓAl_{y}Ga_{1-x-y}P with 0≤x≤1, 0≤y≤1 and x+y≤1. Semiconductor layer sequences which have at least one active layer based on InAlGaP may, for example, such as emit electromagnetic radiation with one or more spectral components in a green to red wavelength range.

Alternatively or additionally, the semiconductor layer sequence may also include other III-V compound semiconductor material systems, such as an InAlGaAs-based material, or II-VI compound semiconductor material systems. In particular, an active layer comprising an InAlGaAs based material may be capable of producing electromagnetic radiation having one or more spectral components in a red to infrared wavelength range.

A II-VI compound semiconductor material may have at least one element from the second main group, such as Be, Mg, Ca, Sr, and one element from the sixth main group, such as O, S, Se. For example, the II-VI compound semiconductor materials include ZnO, ZnMgO, CdS, ZnCdS, MgBeO.

The active layer and, in particular, the semiconductor layer sequence with the active layer may be arranged on a substrate. The substrate may include a semiconductor material, such as a compound semiconductor material system mentioned above, or another material. In particular, the substrate may include or be made of sapphire, GaAs, GaP, GaN, InP, SiC, Si, Ge and/or a ceramic material as for instance SiN or AlN. For example, the substrate may be embodied as a growth substrate on which the semiconductor layer sequence is grown. The active layer and, in particular, a semiconductor layer sequence with the active layer may be grown on the growth substrate by means of an epitaxial process, for example by means of metal-organic vapor phase epitaxy (MOVPE) or molecular beam epitaxy (MBE), and furthermore be provided with electrical contacts. Moreover, it may also be possible that the growth substrate is removed after the growth process. In this case, the semiconductor layer sequence may, for example, also be transferred after growth to a substrate embodied as a carrier substrate.

The active layer may include a conventional pn junction, a double heterostructure, a single quantum well structure (SQW structure) or a multiple quantum well structure (MQW structure) for generating light. The semiconductor layer sequence may include other functional layers and functional regions in addition to the active layer, such as p- or n-doped carrier transport layers, i.e., electron or hole transport layers, highly doped p- or n-doped semiconductor contact layers, undoped or p-doped or n-doped confinement, cladding layers, waveguide layers, barrier layers, planarization layers, buffer layers, protective layers and/or electrical contact layers, and combinations thereof. Moreover, additional layers such as buffer layers, barrier layers and/or protective layers may be arranged also perpendicular to the growth direction of the semiconductor layer sequence, for instance around the semiconductor layer sequence on side surfaces of the semiconductor layer sequence.

In particular, the semiconductor laser device and, thus, the semiconductor layer sequence may include a first cladding layer and a second cladding layer. The active layer is arranged between the first and the second cladding layer in a direction perpendicular to the main extension plane, i.e., along the stacking direction of the semiconductor layer sequence which is the vertical direction. In a non-limiting embodiment, the light-outcoupling surface is arranged on a side of the second cladding layer opposite to the active layer. In other words, the semiconductor laser device may include a semiconductor layer sequence having at least a first cladding layer, and active layer and a second cladding layer, where during operation, light is emitted through the light-outcoupling surface that is situated over the second cladding layer as seen from the active layer. The first cladding layer is arranged between the rear surface and the active layer, and the second cladding layer is arranged between the active layer and the light-outcoupling surface.

According to a further embodiment, the semiconductor laser device may include a photonic crystal layer with at least one photonic crystal structure. Due to the photonic crystal layer, the semiconductor laser device may also be denoted as photonic-crystal semiconductor laser device in the following.

According to at least one further embodiment, a projection device may include at least one semiconductor laser device. In a non-limiting embodiment, the projection device may include more than one semiconductor laser devices. In a non-limiting embodiment, the projection device may include at least one photonic crystal semiconductor laser device, such as, two or more photonic crystal semiconductor laser devices. The embodiments and features described above and in the following apply equally to the semiconductor laser diode and to the projection device.

In a non-limiting embodiment, the photonic crystal layer is arranged in a cladding layer. Accordingly, the photonic crystal layer may be arranged in the first cladding layer or in the second cladding layer. Although in the following the semiconductor laser device is described having one photonic crystal layer, the semiconductor laser device may also include more than one photonic crystal layer, which may be arranged in the same or different cladding layers and, thus, on the same side or on different sides as seen from the active layer. In case the photonic crystal semiconductor laser device includes more than one photonic crystal layer, the photonic crystal layers may have the same or similar features or different features.

The photonic crystal layer may include at least one photonic crystal structure that has a two-dimensional lattice-like matrix of discontinuities in the photonic crystal layer. In a non-limiting embodiment, the discontinuities are arranged next to each other along lateral directions so that the lattice-like matrix extends parallel to the main extension plane of the active layer. In a non-limiting embodiment, the photonic crystal layer may include the discontinuities which have a first refractive index and which are formed as discrete regions in a medium with a second refractive index that is higher than the first refractive index. The medium surrounding the discontinuities may be a semiconductor layer of the semiconductor layer sequence. The discontinuities are formed by a medium with the first refractive index and may be, for instance SiO₂ or air or another gas. In the case of air or another gas, the discontinuities may be formed as holes in the material of the photonic crystal layer.

The photonic crystal layer may be a separate layer, meaning that the cladding layer with the photonic crystal layer may include the photonic crystal layer as a sublayer and at least one additional sublayer that is different from the photonic crystal layer, for instance in regard to the material. Alternatively, the photonic crystal layer may be an integral part of a cladding layer, meaning that the cladding layer is formed by a semiconductor material and that that semiconductor material also surrounds the discontinuities.

In a non-limiting embodiment, the discontinuities may be cylindrical structures extending in the vertical direction and being distributed in lateral directions. The discontinuities and, thus, the photonic crystal layer may have a height, measured in the vertical direction, that is equal to or smaller than a thickness, measured in the vertical direction, of the cladding layer in which the photonic crystal layer is arranged.

The matrix of the discontinuities may be arranged, for example, in a rectangular lattice, a hexagonal lattice, an oblique lattice, or a rotational lattice. The size and distance of the discontinuities with respect to their closest neighbors is on the order of the wavelength of the light produced in the active layer.

The distribution, shape and size of the discontinuities may be regular or irregular. A regular size may mean that the discontinuities have a similar size. The size of a discontinuity may be one or more chosen from a length, a width, a diameter, and an area measured along one or more lateral directions. An irregular size may mean that the discontinuities have different sizes with respect to their respective closest neighbors. A regular shape may mean that all discontinuities have a similar shape, for instance a column-like shape with the same or substantially the same round or polygonal cross-section in a plane parallel to the main extension plane of the active layer. An irregular shape may mean that the discontinuities have different sizes with respect to their respective closest neighbors. A regular distribution may for instance mean that the discontinuities are arranged at similar distances with respect to their respective closest neighbors in the lattice-like structure. An irregular distribution may mean that the lattice-like matrix may be characterized by regularly distributed similar unit cells, each unit cell containing a discontinuity, where the positions of the discontinuities in the unit cells vary from unit cell to unit cell.

The photonic crystal layer provides an optical nanostructure having a periodic or nearly periodic refractive index distribution with dimensions nearly equal to the wavelength of the light produced in the active layer. In the semiconductor layer sequence light is amplified and diffracted by the photonic crystal layer arranged in the vicinity of the active layer. The wavelength of the emitted light depends on the properties of the photonic crystal structure, for instance on one or more of distribution, size and shape of the discontinuities and lattice constant of the matrix. The amplified light is output via the light-outcoupling surface as a laser beam in a direction perpendicular to the surface. Even with a large emission area, the photonic crystal semiconductor laser device may provide a narrow spot beam pattern, having a narrow beam spread angle and circular shape, and a narrow spectral linewidth.

According to a further embodiment, the semiconductor laser device has at least one first emission region and at least one second emission region arranged next to each other in a direction parallel to the main extension plane. In this case, the semiconductor laser device has at least two regions arranged laterally next to each other and may be operated to emit light from the light-outcoupling surface. For example, the two emission regions may be operated independently from each other. Alternatively, the two emission regions may be operated simultaneously.

According to a further embodiment, the photonic crystal layer may include a first photonic crystal structure in the first emission region and a second photonic crystal structure in the second emission region, where the first and the second photonic crystal structures are different. As described above, the wavelength of the light produced in the active layer and amplified in the photonic crystal semiconductor laser device depends on the properties of the photonic crystal structure. Consequently, having two different photonic crystal structures, the photonic crystal semiconductor laser device may produce and emit light with a first wavelength in the first emission region and light with a second wavelength in the second emission region where the second wavelength is different from the first wavelength. Thus, the photonic crystal semiconductor laser device may be configured as a multi-wavelength emitter emitting at least two light beams with different wavelengths. In a non-limiting embodiment, the second wavelength may be slightly detuned with respect to the first wavelength. By overlapping the light beams of the first and second emission regions, such detuning allows, in particular in a projection device, the reduction of interference effects and speckle that could be perceived by an observer. For example, the first emission region may emit light with a central wavelength λ, and the second emission region may emit light with a central wavelength λ+Δλ. For instance, Δλ may range from about 2 nm to about 10 nm, inclusive, or range from 2 nm to 5 nm, inclusive. In a non-limiting embodiment, both the light emitted by the first emission region and the light emitted by the second emission region may have a spectral width, for example an FWHM (full width at half maximum) of several nm, for instance less than 10 nm, or alternatively less than 5 nm. In a non-limiting embodiment, Δλ may be equal to or greater than the FWHM.

In a non-limiting embodiment, the first photonic crystal structure may include a two-dimensional lattice-like first matrix of discontinuities in the photonic crystal layer and the second photonic crystal structure may include a two-dimensional lattice-like second matrix of discontinuities in the photonic crystal layer, where the first and the second two-dimensional matrices differ in regard to one or more parameters, such as lattice constant, density of discontinuities, mean size of discontinuities, material of discontinuities, or combinations thereof. The mean size of the discontinuities of each of the photonic crystal structures may be, for instance, an average diameter or an average area, measured in a plane parallel to the main extension plane of the active layer, of the discontinuities of the respective photonic crystal structure.

Furthermore, the semiconductor laser device may further include at least one third emission region, where the photonic crystal layer may include a third photonic crystal structure in the third emission region and where the third photonic crystal structure is different to both the first and the second photonic crystal structures. Consequently, the third emission region may produce and emit light with a third wavelength that is different from the first and second wavelength. Moreover, the photonic crystal semiconductor laser device may have more than three emission regions emitting light with different wavelengths.

According to a further embodiment, the photonic crystal semiconductor laser device may include a plurality of first emission regions and a plurality of second active regions. For example, the semiconductor laser device may include n×m emission regions with n, m being natural numbers greater than 1, respectively, where n denotes the number of different wavelengths and m denotes the number of emission regions per wavelength.

According to a further embodiment, the projection device may include a plurality of photonic crystal semiconductor laser devices, where the plurality of photonic crystal semiconductor laser devices may include at least a first photonic crystal semiconductor laser device emitting, during operation, light with a first color, and at least a second photonic crystal semiconductor laser device emitting, during operation, light with a second color being different from the first color. A first color being different from a second color is defined herein to mean that the first color and the second color may be perceived differently by a human observer. For instance, the first and the second color may each have a central wavelength separated by more than 50 nm or more than 100 nm. For example, the first color may be red, and the second color may be green.

In addition, the projection device may include at least one third photonic crystal semiconductor laser device emitting, during operation, light with a third color that is different from the first and second colors. As a non-limiting example, the first color may be red, the second color may be green, and the third color may be blue, so that the projection device may be an RGB projection device.

In a non-limiting embodiment, each of the plurality of photonic crystal semiconductor laser devices of the projection device may include at least one first emission region and at least one second emission region, or alternatively, an n×m matrix of first and second emission regions as described above.

According to a further embodiment, the projection system may include an optics system arranged directly downstream of the photonic crystal semiconductor laser devices for directing the first and second light or the first, second, and third light onto an image plane. Advantageously, the photonic crystal semiconductor laser devices may emit light beams with a very low beam divergence, for example of much less than 1°, while the emission regions may have diameters of more than 200 μm. Thus, since the photonic crystal semiconductor laser devices already provide collimated light, the optics system may be simplified in comparison to usual projection systems based, for instance, on edge-emitting laser diodes, and may be free of any collimating optics arranged directly downstream of the photonic crystal semiconductor laser devices for collimating the light emitted by each of the semiconductor laser devices.

According to a further embodiment, the optics system may include one or more scanning mirrors, i.e., one or more movable mirrors that may be used to scan the light beams of the photonic crystal semiconductor laser devices over an image region. In a non-limiting embodiment, the one or more scanning mirrors are based on MEMS (microelectromechanical system) technology.

According to a further embodiment, the optics system may include a beam combining element. The beam combining element may include a lens and/or a beam deflection element. In a non-limiting embodiment, the beam combining element may be arranged directly downstream of the photonic crystal semiconductor laser devices.

According to a further embodiment, the optics system may include at least one liquid-crystal element. The liquid-crystal element(s) may be arranged directly downstream of the photonic crystal semiconductor laser devices. Alternatively, the liquid-crystal element(s) may be arranged directly downstream of a beam combining element. The liquid-crystal element may be, for instance, a liquid-crystal cell (LC cell) that may rotate the light beam polarizations, for instance by an angle between 0° and 90°. The rotation may, for instance, happen and/or alternate with each frame of the projected image in order to reduce speckle and other interference effects.

For example, the liquid-crystal element(s) may be associated with all photonic crystal semiconductor laser devices. In other words, the light beams of all photonic crystal semiconductor laser devices pass through the liquid-crystal element. Alternatively, the liquid-crystal element(s) may include a plurality of liquid-crystal elements where each of the liquid-crystal elements is associated with exactly one of the photonic crystal semiconductor laser devices.

Furthermore, the optics system may include one or more polarizers arranged downstream of the liquid-crystal element(s). The liquid-crystal element(s) may rotate a light beam polarization. The subsequent polarizer may work as a global dimmer that reduces light throughput. This may increase the dynamic range for adapting to the highest and lowest brightness. Although the combination of an LC cell with a polarizer is typically not fast enough for achieving a greyscale-fine resolution, it may be fast enough for global dimming.

As described above, the use of photonic crystal semiconductor laser devices in the projection device allows for a simplified and compact optics system for high brightness environments with a high dimming range and reduced interferences as speckle etc. Each of the photonic crystal semiconductor laser devices may provide a light beam with a high output power, so that images with a high number of pixels, a high brightness and a large field of view (FoV) may be realized. The use of slightly detuned emission regions for each color, i.e., a wavelength mixing for each color, may help to reduce interference effects in the eye of an observer and/or along waveguides. The simple inclusion of additional components in the optics system like LC cells and polarization filters may provide a wide dimming range and a polarization switching to further reduce interferences.

The photonic crystal semiconductor laser device and the projection device described herein may also be used in consumer, industry, and automotive applications. For instance, the projection device may be implemented in a virtual reality (VR) or augmented reality (AR) projection system. The projection device may be a simple photonic-crystal-semiconductor-laser-device-based laser beam scanning system with interference suppression and high dynamic range.

### BRIEF DESCRIPTION OF THE DRAWINGS

Further features, advantages and expediencies will become apparent from the following description of non-limiting embodiments in conjunction with the figures.

FIGS. 1A to 1D show schematic illustrations of a semiconductor laser device according to several embodiments;

FIGS. 2 to 4 show schematic illustrations of a semiconductor laser device according to further embodiments;

FIG. 5 shows a schematic illustration of a projection device according to a further embodiment and

FIGS. 6 to 14 show schematic illustrations of a photonic crystal semiconductor laser device according to further embodiments.

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

### DETAILED DESCRIPTION

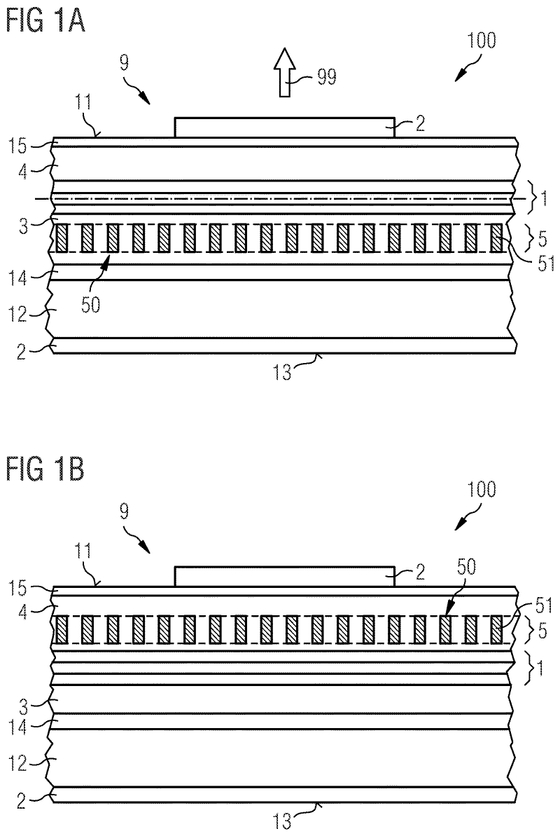

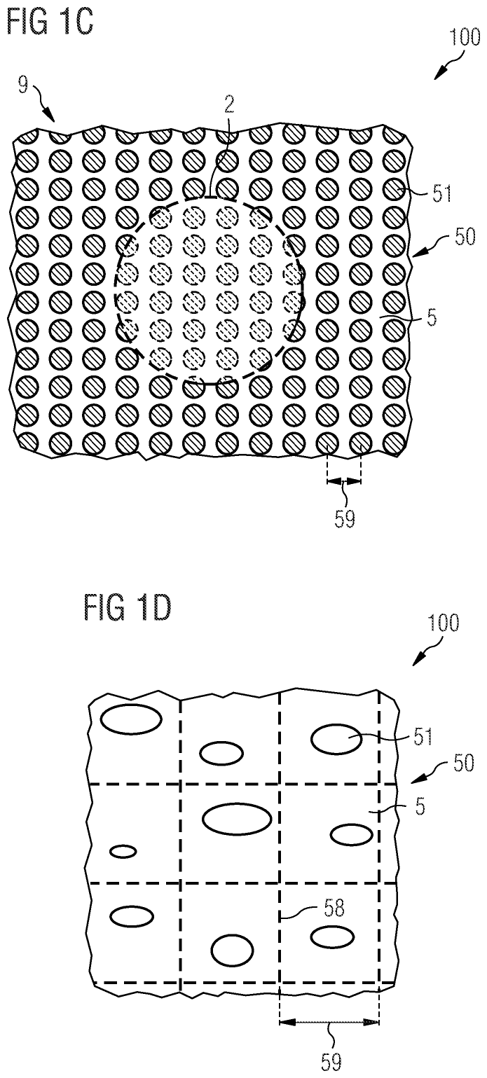

FIGS. 1A to 1D show schematic illustrations of a semiconductor laser device according to several embodiments. In a non-limiting embodiment, the semiconductor laser device may include a photonic crystal layer with at least one photonic crystal structure, thus the semiconductor laser device is referred to as photonic-crystal semiconductor laser device 100 in the following. FIGS. 1A and 1B show sectional views of the photonic crystal semiconductor laser device and FIGS. 1C and 1D show sectional views of the photonic crystal structure of the photonic crystal semiconductor laser device, where in FIG. 1C a position of an electrical contact layer is also indicated. The following description equally applies to all FIGS. 1A to 1D.

As shown in FIG. 1A, the photonic crystal semiconductor laser device 100 may include an active layer 1 configured to generate light 99 in an active region during operation of the photonic crystal semiconductor laser device 100. A main radiation emission direction of the light 99 is indicated by the arrow labelled by the reference numeral 99 in FIG. 1A. The active region determines an emission region 9 of the photonic crystal semiconductor laser device, where the emission region 9 may be configured to emit a light beam with a diameter of more than 100 μm or more than 200 μm.

The active layer 1 is a part of a semiconductor layer sequence 10 having a plurality of semiconductor layers, and has a main extension plane, indicated by the dot-dashed line, perpendicular to an arrangement direction of the layers of the semiconductor layer sequence 10. Directions parallel to the main extension plane of the active layer 1 are denoted as lateral directions, while the arrangement direction of the layers of the semiconductor layer sequence 10 may be denoted as a vertical direction. The light 99 generated in the active layer 1, and especially in the active region during operation of the photonic crystal semiconductor laser diode 100, may be emitted via a light-outcoupling surface 11, with a main radiation emission direction along the vertical direction.

For example, the active layer 1 may have exactly one active region and may include, for instance, an MQW structure for generating light. The active region may at least partially be defined by a contact surface of one or more electrical contact layers 2 with the semiconductor layer sequence 10, i.e., at least partially by a surface through which current is injected into the semiconductor layer sequence 10 and thus into the active layer 1. Although not shown in the figures, the active region may additionally be defined at least partially by structured semiconductor layers, such as current-spreading and/or current-delimiting layers in the semiconductor layer sequence 10. Moreover, the photonic crystal semiconductor laser device 100 may have one or more reflective layers that may contribute to the definition of an active region.

The semiconductor layer sequence 10 may be epitaxially grown. The semiconductor layers of the semiconductor layer sequence 10 may be arranged on a substrate 12 and may include a first cladding layer 3 and a second cladding layer 4. The active layer 1 is arranged between the first and the second cladding layer 3, 4 in a direction perpendicular to the main extension plane, i.e., along the vertical direction. The light-outcoupling surface 11 is arranged on a side of the second cladding layer 4 opposite to the active layer 1. The first cladding layer 3 is arranged between a rear surface 13, which may be a mounting surface of the photonic crystal semiconductor laser device 100, and the active layer 1, and the second cladding layer 4 is arranged between the active layer 1 and the light-outcoupling surface 11.

The semiconductor layer sequence 10 may include further semiconductor layers, such as, a buffer layer 14 and a semiconductor contact layer 15, as well as other semiconductor layers (not shown) like waveguide layers. The layers of the semiconductor layer sequence 10 may be based on a III-V compound semiconductor material system and may include further features as described above in the general part.

The semiconductor layer sequence 10 further includes a photonic crystal layer 5 with a photonic crystal structure 50. The photonic crystal 5 layer is optionally arranged in one of the cladding layers 3, 4. Accordingly, the photonic crystal layer 5 may be arranged in the first cladding layer 3 as shown in FIG. 1A or in the second cladding layer 4 as shown in FIG. 1B. Although in connection with FIG. 1A to 1D as well as the following figures the photonic crystal semiconductor laser device 100 is described having exactly one photonic crystal layer 5, the photonic crystal semiconductor laser device 100 may also include more than one photonic crystal layer, which may be arranged in the same or in different cladding layers 3, 4 and, thus, on the same side or on different sides as seen from the active layer 1. In a non-limiting embodiment, the photonic crystal semiconductor laser device 100 includes more than one photonic crystal layer, and each photonic crystal layer may include the same or different features.

The photonic crystal structure 50 may include a two-dimensional lattice-like matrix of discontinuities 51 in the photonic crystal layer 5 as shown in FIGS. 1C and 1D. The discontinuities 51 are formed by discrete cylindrical structures extending in the vertical direction and are distributed in lateral directions in the photonic crystal layer 5. The discontinuities 51 and, thus, the photonic crystal layer 5 may have a height, measured in the vertical direction, that is equal to or smaller than a thickness, measured in the vertical direction, of the cladding layer 3, 4 in which the photonic crystal layer 5 is arranged.

The matrix of the discontinuities 51 may be arranged, for example, in a rectangular lattice as shown in FIGS. 1C and 1D. Alternatively, other lattice structures are possible, for instance a hexagonal lattice, a rotational lattice or an oblique lattice. The size and distance of the discontinuities 51 with respect to their closest neighbors is on the order of the wavelength of the light produced in the active layer 1.

The discontinuities 51 have a first refractive index, whereas the medium surrounding the discontinuities 51, i.e., the material of the photonic crystal layer 5, has a second refractive index that is different from the first refractive index. In a non-limiting embodiment, the second refractive index is greater than the first refractive index. The medium surrounding the discontinuities 51, i.e., the bulk material of the photonic crystal layer 5, may be formed of a semiconductor material of the semiconductor layer sequence 10. The discontinuities 51 may include or be made of, for instance, SiO₂ or air or another gas. In case of air or another gas, the discontinuities 51 may be formed by holes in the material of the photonic crystal layer 5.

The photonic crystal layer 5 may be a separate layer, meaning that the cladding layer 3, 4 with the photonic crystal layer 5 may include the photonic crystal layer 5 as a sublayer, as indicated by the dashed lines in FIGS. 1A and 1B, and at least one additional sublayer that is different from the photonic crystal layer, for instance in regard to the material. Alternatively, the photonic crystal layer 5 may be an integral part of a cladding layer 3, 4, meaning that the cladding layer 3, 4 including the photonic crystal layer 5 and the material of the photonic crystal layer 5 surrounding the discontinuities 51 are the same material.

The distribution, shape and size of the discontinuities 51 may be regular, as shown in FIGS. 1A to 1C, or irregular, as shown in FIG. 1D. A regular size, as shown for example in FIG. 1C, may mean that the discontinuities 51 have a substantially similar or same size, which may be one or more parameters selected from a length, a width, a diameter, an area, or combinations thereof measured along one or more lateral directions. An irregular size may mean that the discontinuities have different sizes, in particular with respect to their respective closest neighbors, as shown in FIG. 1D. A regular shape, as shown for example in FIG. 1C, may mean that all discontinuities 51 have a similar shape, for example a column-like shape with a round or polygonal cross-section in a plane parallel to the main extension plane of the active layer. An irregular shape, as shown for example in FIG. 1D, may mean that the discontinuities 51 have different sizes, in particular with respect to their respective closest neighbors. A regular distribution may mean that the discontinuities 51 are arranged at similar distances with respect to the respective closest neighbors in the lattice-like structure, as shown in FIG. 1C. Here, the discontinuities 51 may be arranged in a lattice-like manner with a lattice constant 59. An irregular distribution, as shown in FIG. 1D, may mean that the lattice-like matrix may be characterized by regularly distributed similar unit cells 58 with a lattice constant 59, each unit cell 58 containing a discontinuity 51, where the positions of the discontinuities 51 in the unit cells 58 vary from unit cell to unit cell.

The photonic crystal layer 5 provides an optical nanostructure having a periodic or nearly periodic refractive index distribution with dimensions nearly equal to the wavelength of the light produced in the active layer 1. In the semiconductor layer sequence 10, light is amplified and diffracted by the photonic crystal layer 5 arranged in the vicinity of the active layer 1. In a non-limiting embodiment, the photonic crystal layer 5 is arranged close to the active layer 1. For example, an additional reflector layer below the active layer 1 may enhance the output power of the light produced in the semiconductor layer sequence 10. However, it may also be possible that no additional resonator or mirror is necessary.

The photonic crystal layer 5 and the photonic crystal structure 50, i.e., the size, shape and distribution of the discontinuities 51, determine the emission characteristic. In other words, the wavelength of the emitted light 99 may be tuned by the properties of the photonic crystal structure 50, for instance by one or more of distribution, size and shape of the discontinuities 51 and lattice constant 59 of the matrix. The amplified light is output via the light-outcoupling surface 11 as a laser beam. Even with a large area of the active region and, thus, the emission region 9, which may be more than 100 μm or more than 200 μm in diameter. The photonic crystal semiconductor laser device 100 may provide a narrow spot beam pattern, such as having a narrow beam spread angle of less than 1° and with a circular shape, and a narrow spectral linewidth.

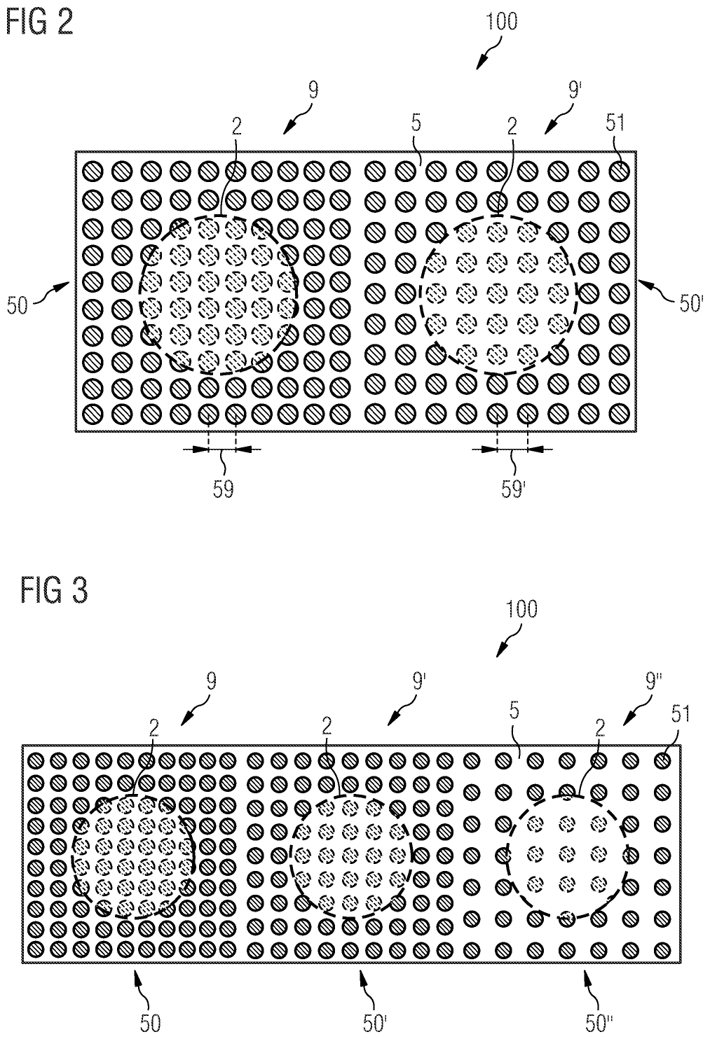

FIGS. 2 to 4 show schematic illustrations of further embodiments of a photonic crystal semiconductor laser device 100. In a non-limiting embodiment, the photonic crystal semiconductor laser devices 100 shown in FIGS. 2 to 4 may include at least two photonic crystal structures 50, 50′, 50″ in the photonic crystal layer 5, resulting in more than one emission region 9, 9′, 9″.

As shown in FIG. 2, the photonic crystal semiconductor laser device may have a first emission region 9 and a second emission region 9′ arranged next to each other in a lateral direction, where each of the emission regions 9, 9′ may be operated to emit light via the light-outcoupling surface. For example, the emission regions 9, 9′ may be operated independently from each other. Alternatively, the two emission regions 9, 9′ may be operated simultaneously.

The photonic crystal layer 5 may include a first photonic crystal structure 50 in the first emission region 9 and a second photonic crystal structure 50′ in the second emission region 9′, where the first and the second photonic crystal structures 50, 50′ are different. In a non-limiting embodiment, the first photonic crystal structure 50 may include a two-dimensional lattice-like first matrix of discontinuities 51 in the photonic crystal layer 5, and the second photonic crystal structure 50′ may include a two-dimensional lattice-like second matrix of discontinuities 51 in the photonic crystal layer 5. The first and the second two-dimensional matrices may differ regarding one or more parameters chosen from a lattice constant 59, 59′, a density of discontinuities 51, a mean size of the discontinuities 51, a material of the discontinuities. The mean size of the discontinuities 51 of each of the photonic crystal structures 50, 50′ may be, for instance, an average diameter or an average area, measured in a plane parallel to the main extension plane of the active layer, of the discontinuities 51 of the respective photonic crystal structure 50, 50′. In the embodiment shown in FIG. 2, the first and second photonic crystal structures 50, 50′ may differ, by way of example, with regard to the lattice constants 59, 59′.

As described above, the wavelength of the light produced in the active layer and amplified in the photonic crystal semiconductor laser device 100 depends on the properties of the photonic crystal structure in an active region. Consequently, the photonic crystal semiconductor laser device 100 shown in FIG. 2 may produce and emit light with a first wavelength from the first emission region 9 and light with a second wavelength from the second emission region 9′ where the second wavelength is different from the first wavelength.

Due to the photonic crystal structures 50, 50′ in the photonic crystal layer 5, the photonic crystal semiconductor laser device 100 may thus be configured as a multi-wavelength emitter emitting at least two light beams with different wavelengths. In a non-limiting embodiment, the second wavelength may be slightly detuned with respect to the first wavelength.

For example, the first emission region may emit light with a central wavelength λ, while the second emission region may emit light with a central wavelength λ+Δλ. Both the light emitted by the first emission region and the light emitted by the second emission region may have a respective spectral width with, for example, an FWHM of several nm, for instance less than 10 nm or less than 5 nm. For example, Δλ may be equal to or greater than the FWHM. This may also mean that Δλ may range from about 2 nm to about 10 nm or from about 2 nm to about 5 nm.

By overlapping the light beams emitted by the first and second emission region 9, 9′, the wavelength detuning causes a reduction of interference effects like speckle patterns that could be perceived by an observer. To a human observer, the light beams emitted by the different emission regions 9, 9′ may appear to have the same color, so that the photonic crystal semiconductor laser device 100 emits, for a human observer, just several light beams with the same color.

In FIG. 3, a further embodiment of the photonic crystal semiconductor laser device 100 is shown that may include a third emission region 9″ in addition to a first and second emission region 9, 9′, where the photonic crystal layer 5 may include a third photonic crystal structure 50″ in the third emission region 9″ and where the third photonic crystal structure 50″ is different to both the first and the second photonic crystal structures 50, 50′. By way of example, the photonic crystal structures 50, 50′, 50″ differ with regard to their respective lattice constants. Due to the differing photonic crystal structures 50, 50′, 50″, the photonic crystal semiconductor laser device 100 may produce and emit light with a third wavelength that is different from the first and second wavelength from the third emission region 9″. For instance, the three emission regions 9, 9′, 9″ may emit light with the wavelengths λ, λ+Δλ and λ+2Δλ, respectively. Moreover, the photonic crystal semiconductor laser device may have more than three emission regions emitting light with different wavelengths.

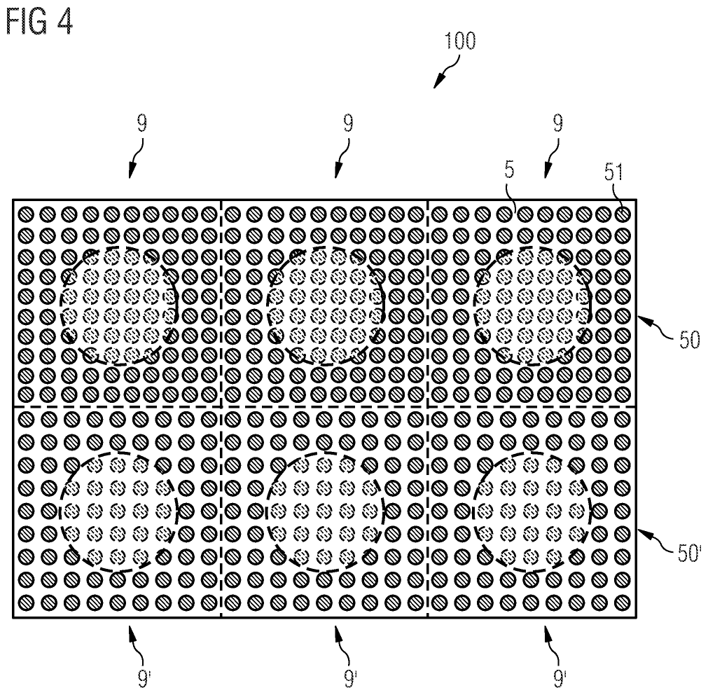

In FIG. 4, a further embodiment of the photonic crystal semiconductor laser device 100 is shown that may include a plurality of first emission regions 9 and a plurality of second emission regions 9′. For example, the photonic crystal semiconductor laser device may include n×m emission regions 9, 9′ with n, m being natural numbers greater than 1, respectively, where n denotes the number of different wavelengths, i.e., then number of different types of emission regions 9, 9′, while m denotes the number of emission regions per wavelength. In the embodiment shown in FIG. 4, the photonic crystal semiconductor laser device may include a 2×3 matrix of emission regions 9, 9′ with three first emission regions 9 and three second emission regions 9′. The shown numbers of different types of emission regions and the shown numbers of emission regions per type are purely exemplary, as other values for n and/or m are possible. By increasing n, the interference/speckle reduction may be increased, while by increasing m the output power per wavelength may be increased.

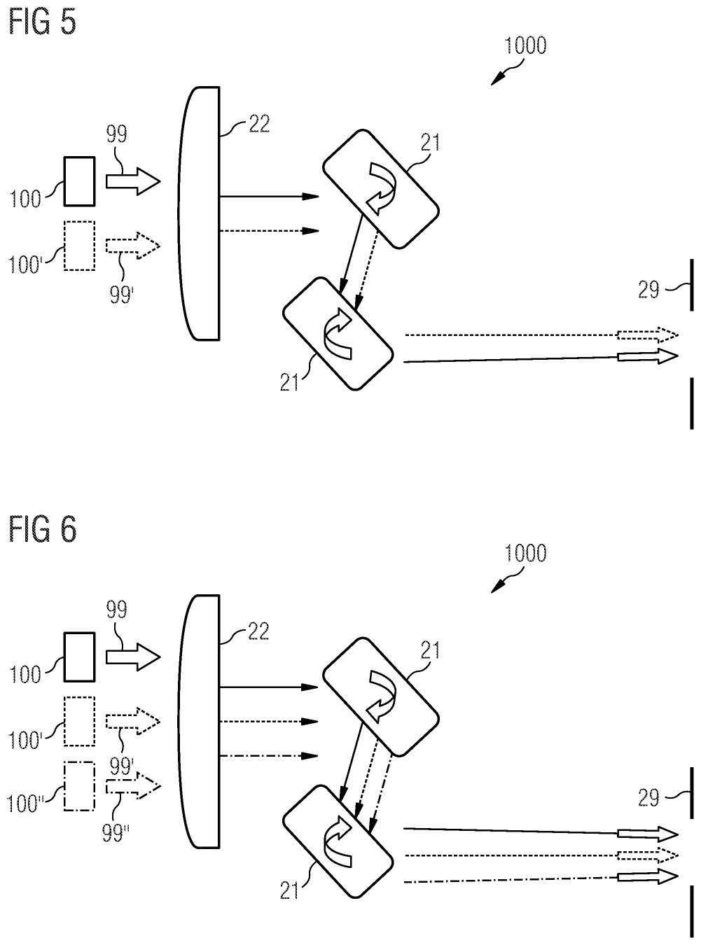

In connection with the following figures, projection devices 1000 are shown, which may contain at least one photonic crystal semiconductor laser device as described in connection with the foregoing embodiments. For instance, the projection device 1000 may have two photonic crystal semiconductor laser devices 100, 100′ as shown in FIG. 5 or three photonic crystal semiconductor laser device 100, 100′, 100″ as shown in FIGS. 6 to 14.

Each of the photonic crystal semiconductor laser devices 100, 100′, 100″ of the projection device 1000 of the embodiments of FIGS. 5 to 14 emits light with a certain color that is different from the colors of the other respective photonic crystal semiconductor laser devices 100, 100′, 100″. Accordingly, the projection device 1000 according to the embodiment of FIG. 5 may include a plurality of photonic crystal semiconductor laser devices 100, 100′, where the plurality of photonic crystal semiconductor laser devices 100, 100′ may include at least a first photonic crystal semiconductor laser device 100 emitting, during operation, light with a first color, and at least a second photonic crystal semiconductor laser device 100′ emitting, during operation, light with a second color different from the first color. In a non-limiting embodiment, the first color and the second color may be perceived as being different by a human observer. For instance, the first and the second color may each be a central wavelength separated by more than 50 nm or more than 100 nm. For example, the first color may be red and the second color may be green.

In addition, as shown in FIGS. 6 to 14, the projection device 1000 may include at least one third photonic crystal semiconductor laser device 100″ emitting, during operation, light with a third color that is different from the first and second color. For example, the first color may be red, the second color may be green, and the third color may be blue, so that the projection device 1000 may be an RGB projection device.

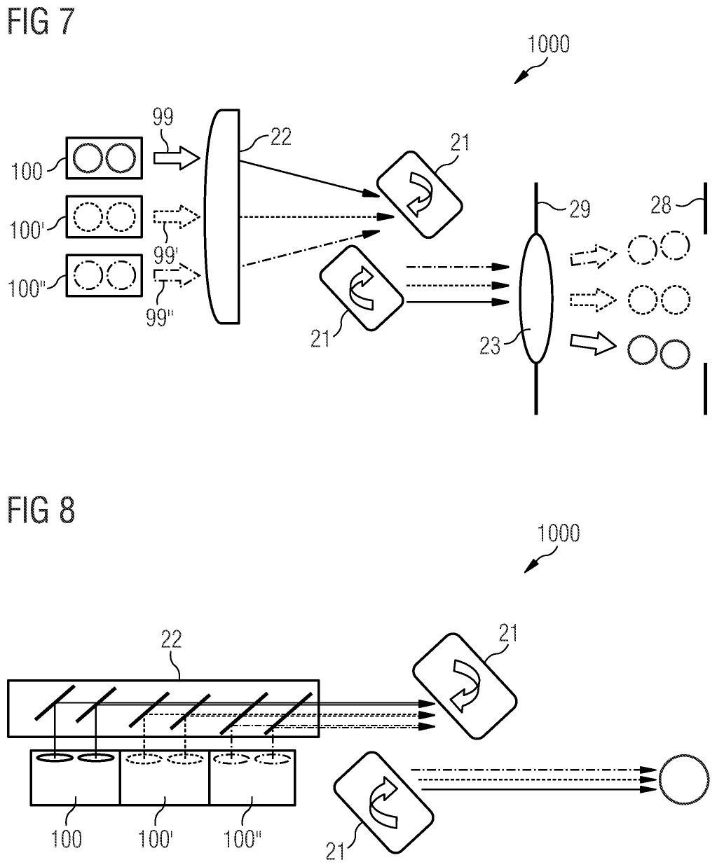

Each of the photonic crystal semiconductor laser devices 100, 100′, 100″ may have one emission region, as shown in FIGS. 5 and 6, or, optionally, more than one emission region, as explained in connection with FIGS. 2 to 4 and as indicated in FIGS. 7 to 14.

The projection device 1000 may optionally be used in consumer, industry and automotive applications. For instance, the projection device 1000 may be implemented in a virtual reality (VR) or augmented reality (AR) projection system.

The use of photonic crystal semiconductor laser devices 100, 100′, 100′ allows for emission regions with a diameter of more than 100 μm diameter, which are emitting already precollimated light with a power that is larger than the power typically emitted by edge-emitting laser diodes used nowadays. Furthermore, one-dimensional or two-dimensional arrays are possible with different emission wavelengths, i.e., with a detuning by some nm from aperture to aperture within one chip. This allows the design of very powerful modules, i.e., modules with high nits. Furthermore, the modules may be compact, since no collimation optics is needed. Moreover, optical losses may be very low, since no fast/slow axis aperture cuts are necessary as it would be necessary in the case of edge-emitting laser diodes. The detuning of the emitted wavelengths additionally allows the reduction of interferences and speckles for each viewer pixel by overlapping the slightly detuned light beams of each of the photonic crystal semiconductor laser devices.

As shown in FIGS. 5 to 14, the projection device 1000 may include an optics system 200 arranged directly downstream of the photonic crystal semiconductor laser devices 100, 100′, 100″ for directing the first and second light or the first, second and third light, as indicated by arrows 99, 99′, 99″, onto an image plane 29. Advantageously, the photonic crystal semiconductor laser devices 100, 100′, 100″ may emit light beams with a very low beam divergence, for example of much less than 1°, while the respective emission regions may have diameters of more than 200 μm. Thus, since the photonic crystal semiconductor laser devices 100, 100′, 100″ already provide collimated light, the optics system 200 may be simplified in comparison to usual projection systems that are based, for instance, on edge-emitting laser diodes, and that may be free of any collimating optics arranged directly downstream of the photonic crystal semiconductor laser devices 100, 100′, 100″ that would be used in connection with, for example, edge-emitting laser diodes. Since no separate fast/slow axis collimation components with cut-off apertures are required, the optics system 200 may be simplified and more efficient as compared to, for instance, projection systems comprising edge-emitting laser diodes.

In a non-limiting embodiment, the optics system 200 may include one or more scanning mirrors 21, i.e., one or more movable mirrors that are used to scan the light beams of the photonic crystal semiconductor laser devices 100, 100′, 100″ over an image region. In a non-limiting embodiment, the one or more scanning mirrors 21 are based on MEMS technology.

Furthermore, the optics system 200 may include a beam combining element 22 configured to substantially only combine the light beams emitted by the photonic crystal semiconductor laser devices 100, 100′, 100″ without collimating them. The beam combining element may include a lens as indicated in FIGS. 5 to 7 and/or a beam deflection element, for instance prisms, as indicated in FIGS. 8 to 14. In a non-limiting embodiment, the beam combining element 22 may be arranged directly downstream of the photonic crystal semiconductor laser devices 100, 100′, 100″ as indicated in FIGS. 5 to 11 and 14.

As further indicated in FIG. 7, the optics system 200 may include an optical component 23 comprising or being a lens, lens system and/or diffuser, which may be used, for instance, for focusing and/or to input the light beams into a waveguide and/or to project the light beams onto an exit pupil 28 and/or as beam widening and/or diffusing element.

As indicated in FIGS. 8 to 10, the light 99, 99′, 99″ emitted by all photonic crystal semiconductor laser devices 100, 100′, 100″ may be perfectly or substantially perfectly overlapped to create a single beam spot. Alternatively, the light 99, 99′, 99″ may be slightly out of alignment, as indicated in FIG. 11, to imperfect the overlap of the different colors and improve the perception of the light beam spot by an observer.

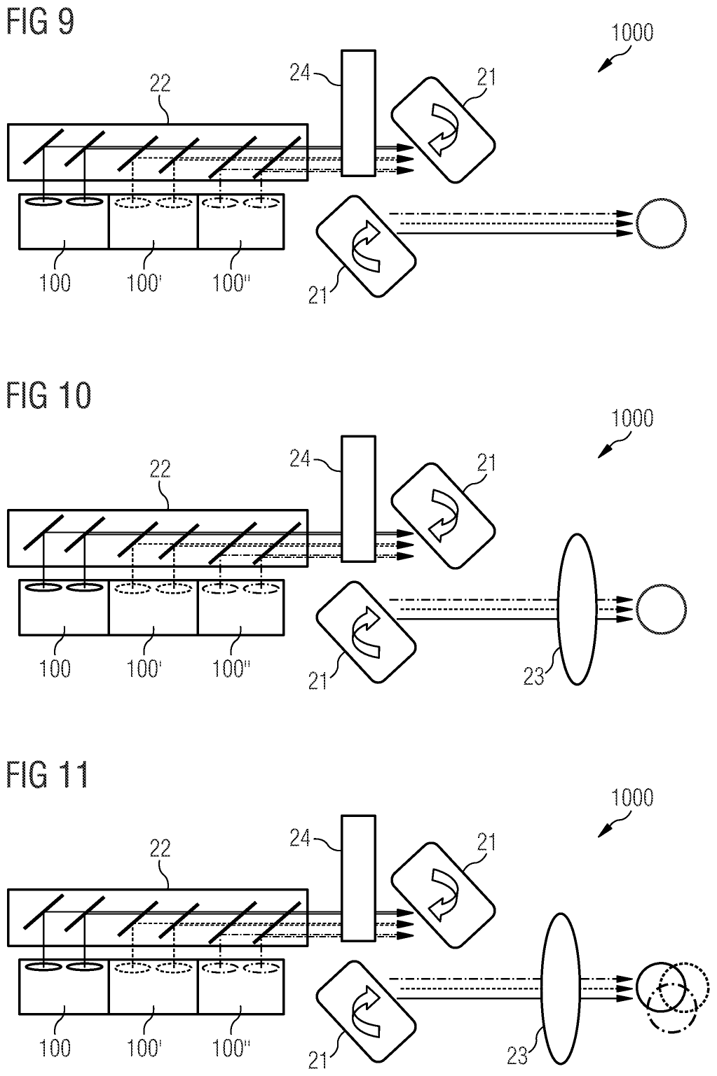

As shown in FIGS. 9 to 11, an optical component 24 may be arranged downstream of the beam combining element 22 that may be used for focusing the combined light beams. Additionally or alternatively, the optical component 24 may include or be a liquid-crystal element. As explained before, the liquid-crystal element may be arranged directly downstream from the beam combining element 22. The liquid-crystal element may be, for instance, an LC cell that may rotate the light beam polarizations, for instance by an angle between 0° and 90°. The rotation may be at least close to orthogonal polarization states and may happen and/or alternate with each frame to reduce speckle and interference effects.

As shown in FIGS. 9 to 11, the liquid-crystal element may be associated with all photonic crystal semiconductor laser devices 100, 100′, 100″. Accordingly, the light 99, 99′, 99″ of all photonic crystal semiconductor laser devices 100, 100′, 100″ passes through the liquid-crystal element. Alternatively, the optical component 24 may include a plurality of liquid-crystal elements, where each of the liquid-crystal elements is associated with exactly one of the photonic crystal semiconductor laser devices 100, 100′, 100″.

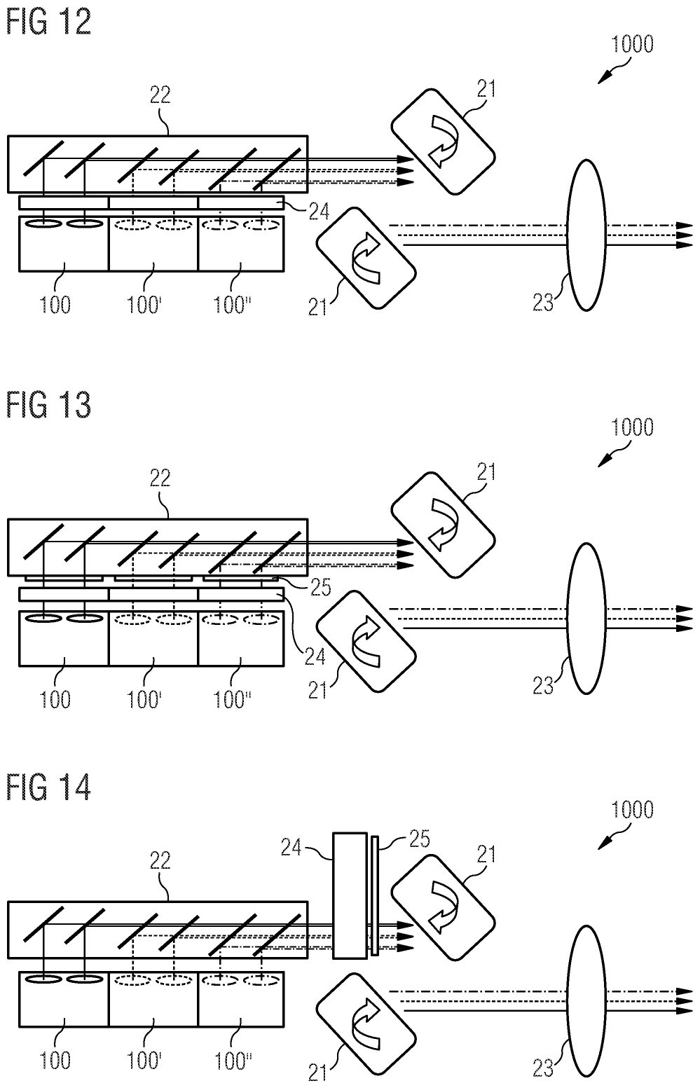

Alternatively, as shown in FIGS. 12 to 14, the optical component 24 comprising one or more liquid-crystal elements may be arranged directly downstream of the photonic crystal semiconductor laser devices 100, 100′, 100″.

Furthermore, the optics system 200 may include one or more polarizers 25 arranged downstream of the liquid-crystal elements. The liquid-crystal elements may rotate a light beam polarization. The subsequent polarizer(s) 25 may work as a global dimmer that reduce(s) the light throughput to increase the dynamic range to adapt to the highest and lowest brightness. Although the combination of an LC cell with a polarizer is typically not fast enough for achieving a greyscale-fine resolution, it may be fast enough for global dimming.

Alternatively or additionally to the features described in connection with the figures, the embodiments shown in the figures may include further features described in the general part of the description. Moreover, features and embodiments of the figures may be combined with each other, even if such combination is not explicitly described.

The invention is not restricted by the description on the basis of the exemplary embodiments. Rather, the invention encompasses any new feature and also any combination of features, which may include any combination of features in the patent claims, even if this feature or this combination itself is not explicitly specified in the patent claims or exemplary embodiments.

### REFERENCE NUMERALS

1 active layer

2 electrical contact layer

3 first cladding layer

4 second cladding layer

5 photonic crystal layer

9, 9′, 9″ emission region

10 semiconductor layer sequence

11 light-outcoupling surface

12 substrate

13 rear surface

14 buffer layer

15 semiconductor contact layer

21 scanning mirror

22 beam combining element

23 optical component

24 optical component

25 polarizer

27 beam spot

28 exit pupil

29 image plane

50, 50′, 50″ photonic crystal structure

51 discontinuity

58 unit cell

59, 59′ lattice constant

99, 99′, 99″ light

100, 100′, 100″ photonic crystal semiconductor laser device

200 optics system

1000 projection device

1. A semiconductor laser device comprising:
an active layer having a main extension plane;
a first cladding layer and a second cladding layer;
wherein the active layer is arranged between the first cladding layer and the second cladding layer in a direction perpendicular to the main extension plane;
at least one first emission region and at least one second emission region arranged next to each other in a direction parallel to the main extension plane;
a light-outcoupling surface parallel to the main extension direction and arranged on a side of the second cladding layer opposite to the active layer;
a photonic crystal layer arranged in the first cladding layer or in the second cladding layer;
wherein the photonic crystal layer comprises a first photonic crystal structure in the first emission region and a second photonic crystal structure in the second emission region; and wherein the first photonic crystal structure and the second photonic crystal structure are different.

2. The semiconductor laser device according to claim 1,
wherein the photonic crystal layer is arranged in the first cladding layer.

3. The semiconductor laser device according to claim 1,
wherein the photonic crystal layer is arranged in the second cladding layer.

4. The semiconductor laser device according to claim 1,
wherein the first photonic crystal structure comprises a two-dimensional lattice-like first matrix of discontinuities in the photonic crystal layer and the second photonic crystal structure comprises a two-dimensional lattice-like second matrix of discontinuities in the photonic crystal layer;
wherein the two-dimensional lattice-like first matrix and the two-dimensional lattice like second matrix differ in regard to one or more parameters selected from the group comprising a lattice constant, a density of discontinuities, a mean size of discontinuities, a material of discontinuities, or combinations thereof.

5. The semiconductor laser device according to claim 4,
wherein the discontinuities are formed by holes.

6. The semiconductor laser device according to claim 1, further comprising at least one third emission region,
wherein the photonic crystal layer comprises a third photonic crystal structure in the third emission region and wherein the third photonic crystal structure is different as compared to both the first photonic crystal structure and the second photonic crystal structure.

7. The semiconductor laser device according to claim 1,
wherein the at least one first emission region comprises a plurality of first emission regions; and wherein the at least one second emission region comprises a plurality of second emission regions.

8. A projection device comprising:
a plurality of photonic crystal semiconductor laser devices; and
an optics system arranged directly downstream from the photonic crystal semiconductor laser devices for directing a first light and a second light onto an image plane;
wherein the plurality of photonic crystal semiconductor laser devices comprises at least a first photonic crystal semiconductor laser device configured to emit the first light with a first color;
wherein the plurality of photonic crystal semiconductor laser devices comprises at least a second photonic crystal semiconductor laser device configured to emit the second light with a second color being different from the first color.

9. The projection device according to claim 8, wherein each of the plurality of photonic crystal semiconductor laser devices comprises:
an active layer having a main extension plane;
a first cladding layer and a second cladding layer;
wherein the active layer is arranged between the first cladding layer and the second cladding layer in a direction perpendicular to the main extension plane;
at least one first emission region and at least one second emission region arranged next to each other in a direction parallel to the main extension plane;
a light-outcoupling surface parallel to the main extension direction and arranged on a side of the second cladding layer opposite to the active layer;
a photonic crystal layer arranged in the first cladding layer or in the second cladding layer;
wherein the photonic crystal layer comprises a first photonic crystal structure in the first emission region and a second photonic crystal structure in the second emission region; and wherein the first photonic crystal structure and the second photonic crystal structure are different.

10. The projection device according to claim 8, wherein the optics system comprises one or more scanning mirrors.

11. The projection device according to claim 8, wherein the optics system is free from any collimating optics arranged directly downstream of the plurality of photonic crystal semiconductor laser devices for collimating the light emitted by each of the semiconductor laser devices.

12. The projection device according to claim 8, wherein the optics system comprises a beam combining element.

13. The projection device according to claim 12, wherein the beam combining element comprises a lens and/or a beam deflection element.

14. The projection device according to claim 12, wherein the beam combining element is arranged directly downstream of the plurality of photonic crystal semiconductor laser devices.

15. The projection device according to claim 8, wherein the optics system comprises at least one liquid-crystal element.

16. The projection device according to claim 15, wherein the at least one liquid-crystal element is arranged directly downstream of the plurality of photonic crystal semiconductor laser devices.

17. The projection device according to claim 15, wherein the at least one liquid-crystal element is associated with all photonic crystal semiconductor laser devices.

18. The projection device according to claim 15, wherein the at least one liquid-crystal element comprises a plurality of liquid-crystal elements, wherein each of liquid-crystal element of the plurality of liquid-crystal elements is associated with exactly one photonic crystal semiconductor laser device of the plurality of photonic crystal semiconductor laser devices.

19. The projection device according to claim 15, wherein the at least one liquid-crystal element is arranged downstream of a beam combining element.

20. The projection device according to claim 15, wherein the optics system comprises one or more polarizers arranged downstream of the at least one liquid-crystal element.
